(19) United States
(12) Patent Application Publication
(10) Pub. No.: US 2025/0297810 A1
(43) Pub. Date: Sep. 25, 2025

(54) VAPOR CHAMBER STRUCTURE WITH PARTIALLY INCREASED PLATE THICKNESS

(71) Applicant: TAIWAN MICROLOOPS CORP., New Taipei City (TW)

(72) Inventor: Chun-Hung LIN, New Taipei City (TW)

(21) Appl. No.: 18/639,983

(22) Filed: Apr. 19, 2024

(30) Foreign Application Priority Data
Mar. 19, 2024 (TW) 113110185

(51) Int. Cl. F28D 15/02; F28D 15/04

(52) U.S. Cl. CPC F28D 15/0233; F28D 15/046

(57) ABSTRACT

A vapor chamber structure with a partially increased plate thickness includes an upper plate and a lower plate. The lower plate is superposed with the upper plate. A chamber is formed between the upper plate and the lower plate. Multiple support structures supported between the upper plate and the lower plate are disposed in the chamber. The lower plate includes a first lower plate and a second lower plate. The first lower plate has a first thickness. The second lower plate is disposed with a through hole for being inserted by the first lower plate to be closely connected. The through hole has a second thickness. The first thickness is greater than the second thickness. A part which touches a heat source can be partially thickened to improve the effect of heat transfer contact by the different thicknesses of the first lower plate and the second lower plate.

### BACKGROUND

### Technical Field

The disclosure relates to a heat conduction element, particularly to a vapor chamber structure with a partially increased plate thickness.

### Related Art

In a related-art vapor chamber, there is a wick structure in both the upper plate and the lower plate, and the working fluid inside the vapor chamber generates a vapor phase change when heated, thereby transferring the heat from the heated lower plate rapidly to the upper plate through heat conduction, then the vaporized working fluid returns to a liquid state after condensation through the upper plate, and finally flows back into the lower plate from the wick structure.

However, since related-art vapor chambers are often used in thinned electronic products, the upper plate and the lower plate are also relatively thinned in thickness, making it impossible to use a thicker plate to contact a heat source and store heat. Therefore, it needs to be improved. In view of this, the inventors have devoted themselves to the above-mentioned prior art, researched intensively and cooperated with the application of science to try to solve the above-mentioned problems. Finally, the invention which is reasonable and effective to overcome the above drawbacks is provided.

### SUMMARY

An object of the disclosure is to provide a vapor chamber structure with a partially increased plate thickness, which uses junction to make the lower plate used for touching a heat source constituted by joining different thicknesses to partially thicken a part which is used to touch the heat source to improve the effect of heat transfer contact of vapor chamber.

To accomplish the above object, the disclosure provides a vapor chamber structure with a partially increased plate thickness, which includes an upper plate and a lower plate. The lower plate is superposed with the upper plate. A chamber is formed between the upper plate and the lower plate. Multiple support structures supported between the upper plate and the lower plate are disposed in the chamber. The lower plate includes a first lower plate and a second lower plate. The first lower plate has a first thickness. The second lower plate is disposed with a through hole for being inserted by the first lower plate to be closely connected. The through hole has a second thickness. The first thickness is greater than the second thickness.

### BRIEF DESCRIPTION OF THE DRAWINGS

FIG. 1 is a cross-sectional schematic view of the internal structure of the first embodiment of the disclosure;

FIG. 2 is a cross-sectional exploded schematic view of the upper plate and the lower plate of the first embodiment of the disclosure;

FIG. 3 is a partially exploded schematic view of the upper plate and the lower plate of the first embodiment of the disclosure;

FIG. 4 is a partially cross-sectional schematic view of the first embodiment of the disclosure;

FIG. 5 is a partially cross-sectional schematic view of the second embodiment of the disclosure;

FIG. 6 is a partially cross-sectional schematic view of the third embodiment of the disclosure;

FIG. 7 is a partially cross-sectional schematic view of the fourth embodiment of the disclosure;

FIG. 8 is a partially cross-sectional schematic view of the fifth embodiment of the disclosure; and

FIG. 9 is a partially cross-sectional schematic view of the sixth embodiment of the disclosure.

### DETAILED DESCRIPTION

The technical contents of this disclosure will become apparent with the detailed description of embodiments accompanied with the illustration of related drawings as follows. It is intended that the embodiments and drawings disclosed herein are to be considered illustrative rather than restrictive.

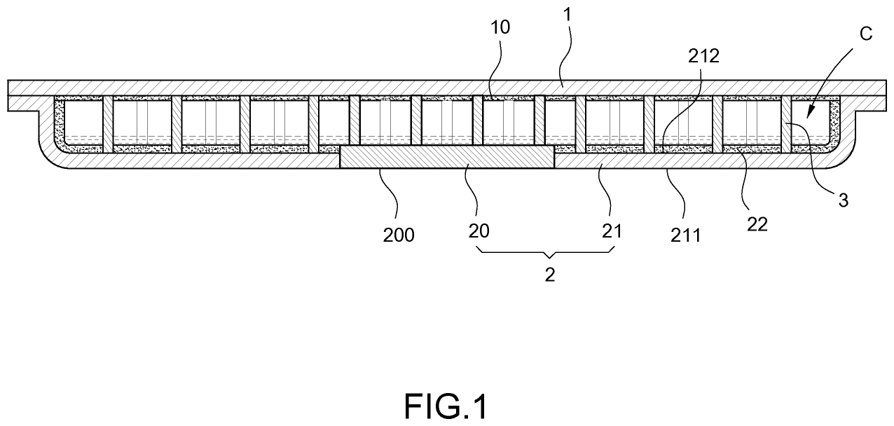

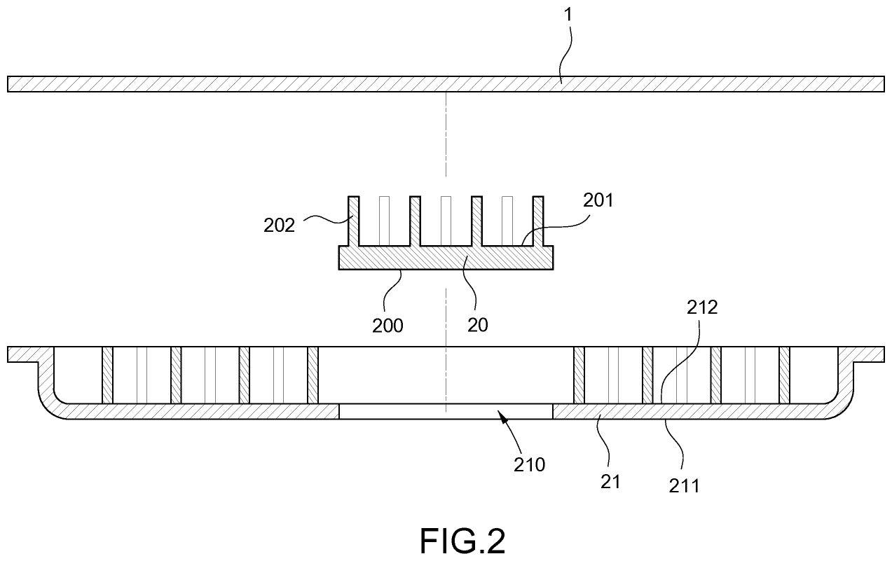

Please refer to FIGS. 1 and 2, which are a cross-sectional schematic view of the internal structure of the first embodiment of the disclosure and a cross-sectional exploded schematic view of the upper plate and the lower plate of the first embodiment of the disclosure, respectively. The disclosure provides a vapor chamber structure with a partially increased plate thickness, which includes an upper plate 1 and a lower plate 2.

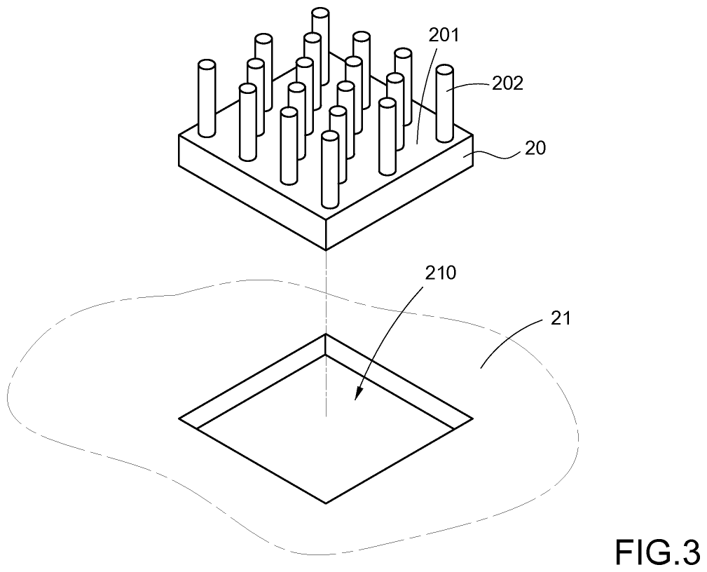

The upper plate 1 and the lower plate 2 may be made of a material with great thermal conductivity such as copper or aluminum. The lower plate 2 is composed of a first lower plate 20 and a second lower plate 21. Please refer to FIG. 3 together. The second lower plate 21 is disposed with a through hole 210. The through hole 210 matches with the contour of the first lower plate 20 to be formed so that the first lower plate 20 can be disposed on the through hole 210 by a manner of tight fit or tightening. And the second lower plate 21 and the first lower plate 20 are closely connected by a manner such as welding to constitute the lower plate 2.

Please refer to FIGS. 1 and 2. The upper plate 1 is covered on the lower plate 2 to form a chamber C between the upper plate 1 and the lower plate 2. In detail, the second lower plate 21 of the lower plate 2 may be formed with an indent toward the upper plate 1 to make the indent covered by the upper plate 2 and sealedly joined with the periphery of the second lower plate 21 to form the chamber C when covered with the upper plate 2. In addition, as shown in FIG. 1, a surface of the upper plate 1, which is opposite to the lower plate 2, may be disposed with an upper wick structure 10. The upper wick structure 10 is located in the chamber C and may be constituted by woven mesh, powder sintered or grooves formed on a surface of the upper plate 1.

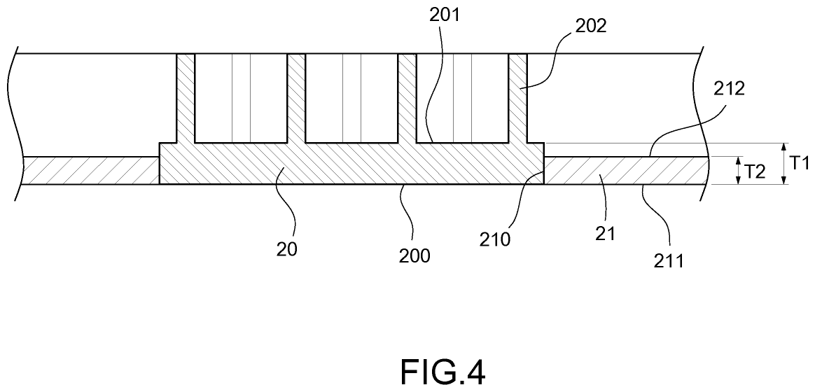

As shown in FIG. 4, the disclosure makes the first lower plate 20 of the lower plate 2 have a first thickness T1 and the second lower plate 21 of the lower plate 2 have a second thickness T2. The thickness of the through hole 210 disposed in the second lower plate 21 is substantially the same as the second thickness T2. The first thickness T1 is greater than the second thickness T2. As a result, an effect of partially thickening can be accomplished by the first thickness T1 of the first lower plate 21 so that the first lower plate 21 can be used to contact a heat source (not shown) and has functions of great heat storage and heat transfer.

Therefore, the vapor chamber structure with a partially increased plate thickness of the disclosure can be obtained by the above structure.

Please refer to FIGS. 1-4. In the shown embodiments of the disclosure, multiple support structures 3 supported between the upper plate 1 and the lower plate 2 may be disposed in the chamber C mentioned above. Furthermore, the first lower plate 20 of the lower plate 2 has a contact surface 200 and an inner surface 201 opposite to the contact surface 200. The inner surface 201 of the first lower plate 20 may also be disposed with multiple support portions 202. The support portions 202 may be the support structures 3 mentioned above (i.e., the support structures 3 may also be the support portions 202 on the inner surface 201 of the first lower plate 20) or the support structures 3 and the support portions 202 exist simultaneously. The support portions 202 may be integratedly formed with the first lower plate 20 such as extrusion forming. Furthermore, the second lower plate 21 has an outer surface 211 and an inner surface 212. The inner surface 212 may be disposed with a lower wick structure 22. The lower wick structure 22 is located in the chamber C and may be woven mesh, powder sintered or grooves formed on the inner surface 212. The contact surface 200 of the first lower plate 20 may be flush with the outer surface 211 of the second lower plate 21 to allow the inner surface 201 of the first lower plate 20 to stretch into the chamber C. Also, the support structures 3 mentioned above are supported between the upper plate 1 and the inner surface 212 of the second lower plate 21.

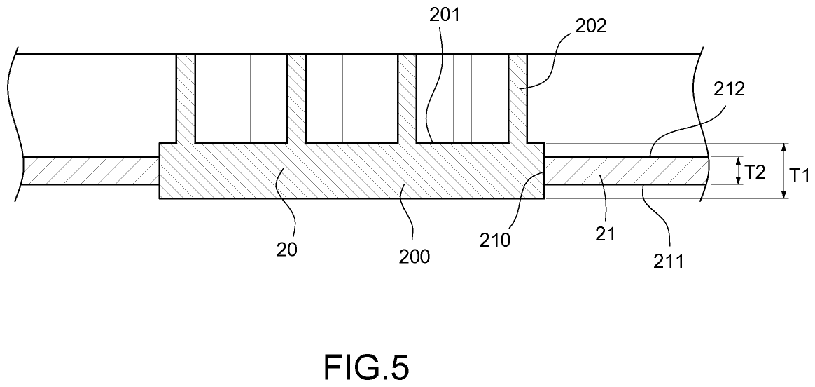

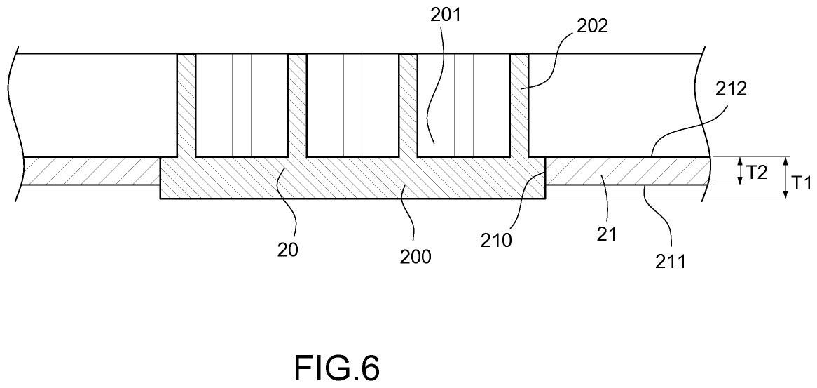

In addition, as shown in FIG. 5, the contact surface 200 and the inner surface 201 of the first lower plate 20 mentioned above may project from the outer surface 211 and the inner surface 212 of the second lower plate 21. That is, the first lower plate 20 is placed at a height position of the through hole 210. Of course, as shown in FIG. 6, the inner surface 201 of the first lower plate 20 may also be flush with the inner surface 212 of the second lower plate 21 to make the contact surface 200 of the first lower plate 20 project from the outer surface 211 of the second lower plate 21.

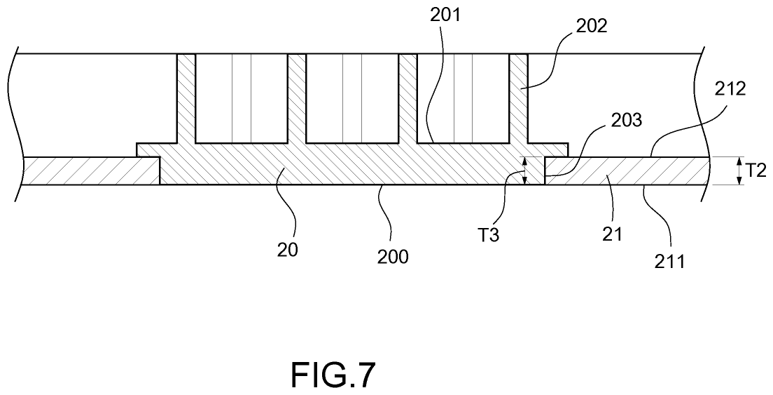

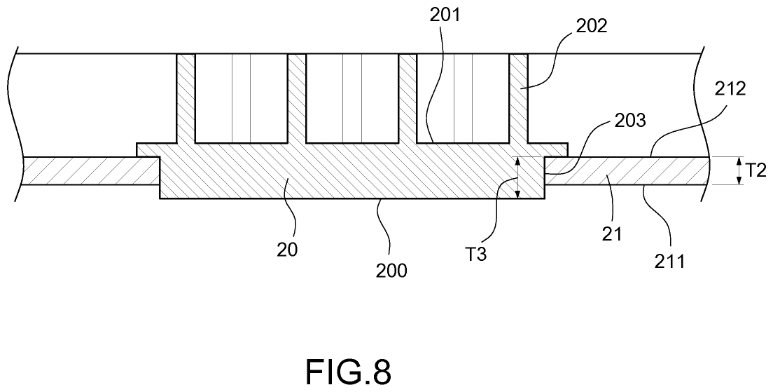

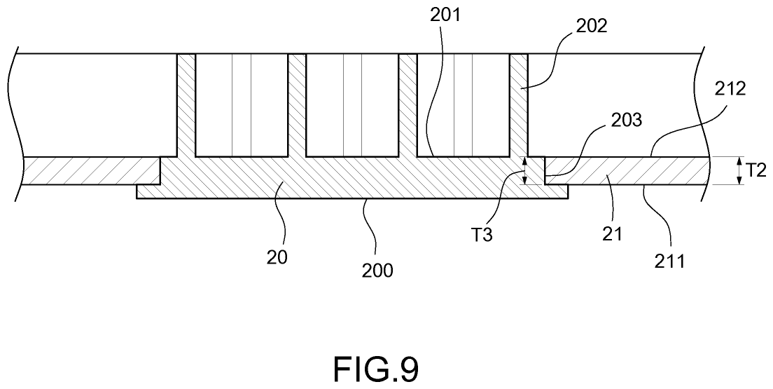

Moreover, as shown in FIGS. 7-9, furthermore, the disclosure may form a dented edge 203 on the first lower plate 20 mentioned above, which matches with the through hole 210 of the second lower plate 21. The dented edge 203 has a third thickness T3. The third thickness T3 is substantially greater than or equal to the second thickness T2, so that the first lower plate 20 can be expectably joined on the through hole 210 of the second lower plate 21. Identically, as shown in FIG. 7, when the dented edge 203 is substantially equal to the second thickness T2 and adjacent to the contact surface 200 of the first lower plate 20, the contact surface 200 of the first lower plate 20 is flush with the outer surface 211 of the second lower plate 21. As shown in FIG. 8, when the dented edge 203 is substantially greater than the second thickness T2, the contact surface 200 of the first lower plate 20 can project from the outer surface 211 of the second lower plate 21 or the inner surface 201 of the first lower plate 20 projects from the inner surface 212 of the second lower plate 21 (not shown). As shown in FIG. 9, when the dented edge 203 is substantially equal to the second thickness T2 and adjacent to the inner surface 201 of the first lower plate 20, the inner surface 201 of the first lower plate 20 is flush with the inner surface 212 of the second lower plate 21. Thus, variations of the above embodiments can still be implemented by the dented edge 203.

While this disclosure has been described by means of specific embodiments, numerous modifications and variations could be made thereto by those skilled in the art without departing from the scope and spirit of this disclosure set forth in the claims.

What is claimed is:

1. A vapor chamber structure with a partially increased plate thickness, comprising:
an upper plate; and
a lower plate, superposed with the upper plate, a chamber being formed between the upper plate and the lower plate, and multiple support structures supported between the upper plate and the lower plate being disposed in the chamber;
wherein the lower plate comprises a first lower plate and a second lower plate, the first lower plate comprises a first thickness, the second lower plate is disposed with a through hole for being inserted by the first lower plate to be closely connected, the through hole comprises a second thickness, and the first thickness is greater than the second thickness.

2. The vapor chamber structure with a partially increased plate thickness of claim 1, wherein the upper plate comprises a surface opposite to the lower plate, and the surface of the upper plate is disposed with an upper wick structure.

3. The vapor chamber structure with a partially increased plate thickness of claim 1, wherein the second lower plate of the lower plate is formed with an indent toward the upper plate to form the chamber.

4. The vapor chamber structure with a partially increased plate thickness of claim 1, wherein the first lower plate is formed with a dented edge which matches with the through hole, the dented edge comprises a third thickness, and the third thickness is substantially greater than or equal to the second thickness.

5. The vapor chamber structure with a partially increased plate thickness of claim 1, wherein the second lower plate and the first lower plate are closely connected by welding.

6. The vapor chamber structure with a partially increased plate thickness of claim 1, wherein the first lower plate comprises a contact surface, and the contact surface projects from the outer surface of the second lower plate or is flush with the outer surface of the second lower plate.

7. The vapor chamber structure with a partially increased plate thickness of claim 1, wherein the first lower plate comprises an inner surface, and the inner surface of the first lower plate is disposed with multiple support portions.

8. The vapor chamber structure with a partially increased plate thickness of claim 7, wherein the support portions are integratedly formed with the first lower plate.

9. The vapor chamber structure with a partially increased plate thickness of claim 7, wherein the second lower plate comprises an inner surface, and the support structures are supported between the upper plate and the inner surface of the second lower plate.

10. The vapor chamber structure with a partially increased plate thickness of claim 9, wherein the inner surface of the second lower plate is disposed with a lower wick structure.
